(19) United States
(12) Patent Application Publication
(10) Pub. No.: US 2024/0036345 A1
(43) Pub. Date: Feb. 1, 2024

(54) METHOD AND APPARATUS FOR THE OPTICAL CONTACT BONDING OF COMPONENTS

(71) Applicant: Carl Zeiss SMT GmbH, Oberkochen (DE)

(72) Inventors: Stefan SCHUETTER, Herbrechtingen (DE); Eduard SCHWEIGERT, Syrgenstein (DE); Benjamin ROSS, Aalen (DE); Sebastian FAAS, Dornstadt (DE)

(21) Appl. No.: 18/485,370

(22) Filed: Oct. 12, 2023

Related U.S. Application Data
(63) Continuation of application No. PCT/EP2022/059203, filed on Apr. 7, 2022.

(30) Foreign Application Priority Data
Apr. 12, 2021 (DE) 10 2021 203 570.1

(51) Int. Cl. G02B 27/62; B81C 3/00; B81B 1/00

(52) U.S. Cl. CPC G02B 27/62; B81C 3/001; B81B 1/006; B81C 2203/038; B81B 2201/042

(57) ABSTRACT

A method for optical contact bonding components includes: placing a first surface (2a) of a first component (2) onto a second surface (3a) of a second component (3), to form an air film, and pressing the first surface against the second surface for optical contact bonding of the two components. Placing and pressing the first component is carried out by a robot (4). A laminar gas flow (10) is generated between the first and second surfaces with a ventilation device (9). A related apparatus (1) includes: the robot, configured to place the first surface onto the second surface thereby forming an air film. The robot presses the first surface against the second surface, to optically contact bond the first and second components. A holding device (8) holds the second component during the placing and pressing. A ventilation device generates the laminar gas flow between the first and second surfaces.

### CROSS-REFERENCE TO RELATED APPLICATION

This is a Continuation of International Application PCT/EP2022/059203, which has an international filing date of Apr. 7, 2022, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2021 203 570.1 filed on Apr. 12, 2021.

### FIELD OF THE INVENTION

The invention relates to a method for the optical contact bonding of (two or more) components, comprising: placing a first surface of a first component onto a second surface of a second component so as to form an air film, and pressing the first surface of the first component against the second surface of the second component for the optical contact bonding of the first component to the second component. The invention also relates to an apparatus for the optical contact bonding of components which is suitable, in particular, for carrying out the method for the optical contact bonding of components.

### BACKGROUND

Optical contact bonding is a connection of two materials in which the surfaces which bear against one another are held only by molecular forces of attraction, that is to say without a joining substance such as an adhesive, such that the connection can be partially or completely released (for example under the influence of moisture or a wedge effect). Optical contact bonding can be used with various materials, e.g. with ceramic materials or with glass materials.

Optical contact bonding is typically effected manually, the second component being oriented horizontally or abutting against a horizontally oriented support surface. The first surface of the first component is first of all carefully placed onto the surface of the second component and “floats” on an air film on the surface of the second component. A prerequisite for the formation of the air film is that the two surfaces have substantially the same geometry and are sufficiently smooth.

The weight force of the first component is generally not sufficient to displace the air film and trigger the actual optical contact bonding process in the case of such an areal abutment. Manual pressing of the first surface of the first component against the second surface of the second component therefore has the effect of displacing the air film between the surfaces, such that the two surfaces touch and the actual optical contact bonding process takes place, in which the two surfaces are connected to one another by molecular forces of attraction.

For optical contact bonding, the surfaces not only have to be very smoothly polished (flatness and surface imperfection or surface roughness typically in the range of 50-200 nm), but also have to be free from dust or particles, grease or hydrocarbons or any other soiling. The surfaces of the components are therefore typically cleaned prior to the optical contact bonding. Unevennesses and particle contamination on the surfaces to be optically contact bonded can result in the two components not being able to be brought into sufficiently close contact with one another in order for attracting interactions to form between the surfaces. However, in optical contact bonding there is the risk in particular—but not only—during the horizontal handling of the components that particles trickle onto the surface of the second component and result in inclusions, what are known as voids, after the optical contact bonding. These voids are flaws which weaken the connection and—if they occur at the wrong location—can result in the component part composed of the two components being rejected.

Optical contact bonding is an established process in precision optics and is utilized to connect components in the form of lenses. The components which are optically contact bonded to one another may alternatively form—possibly with further components which are fastened thereto—composite structures for lithography. Such a composite structure may form a holding apparatus for a wafer or a mirror for reflection of EUV radiation, as is described, for example, in WO2013/021007 A1. There are also areas of application for optical contact bonding in the semiconductor industry, in which a partially automated positioning of the components is effected and various process auxiliaries are used for the actual optical contact bonding operation.

U.S. Pat. No. 6,814,833B2 describes a method for the direct bonding of silicon-containing components, in which functional groups are generated on the surfaces to be connected. For the generation of the functional groups, the surfaces are brought into contact with a solution having a high pH, typically between 8 and 13.

US 2003/0079503 A1 describes a method for the direct bonding of glass components for a subsequent glass drawing process. For the direct bonding, the components can be brought into contact with an acid or with a solution having a pH greater than 8.

The article “Wafer direct bonding: tailoring adhesion between brittle materials”, A. Plöβl, G. Kräuter, Materials Science & Engineering R 25 (1-2), p 1-88 (1999) describes, inter alia, methods for changing the surface chemistry for the adaptation of bonding properties.

Different methods for the direct bonding of wafers, for example a plasma-activated low-temperature bonding method, are also described in the dissertation “Direct wafer bonding for MEMS and microelectronics”, Tommi Suni, VTT Publications 609.

### SUMMARY

One object of the invention is to provide a method and an apparatus for the optical contact bonding of components, the risk of inclusions between the surfaces being reduced in said method and apparatus.

According to one formulation, this object is achieved with a method of the type mentioned in the introduction, in which the step of placing the first component and preferably the step of pressing the first component is carried out by a robot.

The inventor has recognized that if the optical contact bonding is carried out manually, the risk of voids or inclusions forming during the optical contact bonding is increased considerably even when the optical contact bonding is carried out in a clean room, since humans represent the greatest source of particles in the clean room. The invention therefore proposes carrying out at least the placing step, possibly also the pressing step, with the aid of a robot. The robot holds the first component and carries out the placing step, and possibly the pressing step, in an automated manner, without a human needing to be present in the vicinity of the components for this purpose.

Tests have shown that the placing of the first surface of the first component onto the second surface of the second component so as to form an air gap is possible with the aid of a robot, without the optical contact bonding being triggered directly in this step by a force effect or by the pressing of the first surface of the first component against the second surface of the second component. However, in principle, it is also possible for the placing and pressing steps to be performed with the aid of the robot simultaneously instead of successively. In this case, during the placing with the aid of the robot, a force which is great enough to trigger the optical contact bonding operation is exerted on the second component. In both cases, it has been observed that, after the optical contact bonding, the interconnected components did not exhibit any inclusions or bubbles or the number of inclusions or bubbles was reduced considerably.

In principle, it is possible for only the placing step to be carried out with the aid of the robot. In this case, the pressing step is effected manually, when the two surfaces areally abut against one another. Since the air film formed during the placing operation has a thickness in the micrometer range, the risk of particles being deposited between the two surfaces is low when said surfaces are manually pressed against one another in the abutting state. However, such a partially automated optical contact bonding operation with a manual pressing operation is dependent on the experience of the operator and is therefore reproducible only to a limited extent. The manual activation or the manual pressing of the components results in undefined surface states and typically does not enable any qualification of the surfaces and of the optical contact bonding operation itself. If the robot performs the pressing operation, it generates a pressing force or a corresponding torque which is strong enough to initiate the optical contact bonding.

Furthermore, in the method according to the invention a laminar gas flow is generated between the first surface of the first component and the second surface of the second component with a ventilation device.

In one variant, the second component is oriented at an angle with respect to a horizontal plane, in particular vertically (i.e. at an angle of 90° with respect to the horizontal plane), during the placing and preferably during the pressing of the first component. As has been described further above, when the second component is oriented horizontally there is the risk of particles settling under the action of gravity on the second surface of the second component. The orientation of the second component at an angle with respect to the horizontal, in particular in a vertical orientation, reduces the risk of particles being deposited on the second surface of the second component. In the case of a planar second surface, the angle between the second component and a horizontal plane is measured between the horizontal plane and the second surface. If the second surface is not planar, the angle is measured with respect to a reference surface of the second component. Typically, the reference surface is a planar surface of the second component with which said second component would abut against a support surface in the horizontal orientation.

In a further variant, the laminar gas flow is generated between the first surface of the first component and the second surface of the second component with the ventilation device such that it is preferably oriented at an angle with respect to a horizontal plane, in particular vertically, or is oriented horizontally or substantially horizontally (i.e. at an angle of +/−20° with respect to the horizontal plane). If the gas flow is oriented at an angle with respect to a horizontal plane, in particular vertically, the flow direction of the gas flow usually runs from top to bottom, i.e. in the direction of gravity or substantially in the direction of gravity. This variant is expedient in particular when the second component is oriented at an angle with respect to the horizontal plane, in particular vertically, since in this case particles which pass between the two surfaces can be entrained by the gas flow substantially in the direction of gravity. Even if the second component is oriented (substantially) horizontally during the optical contact bonding, it is favorable for a laminar gas flow to be generated between the surfaces of the two components. In this case, the laminar gas flow may be oriented in particular substantially in a horizontal direction.

For the generation of the gas flow, use may be made of a ventilation device, for example what is known as a fan filter unit (FFU), as is used in clean rooms. Such a fan filter unit comprises a fan and a filter, said fan drawing in air from above and blowing a gas flow in the form of a laminar air flow through the filter into the clean room, said air flow typically being oriented in a vertical direction, i.e. in the direction of gravity. For the generation of a gas flow which runs (substantially) in the horizontal direction with the aid of a fan filter unit, a portion of the gas that has passed through the filter can be branched off. However, it is also possible in this case to use an independent ventilation device, which provides (cleaned or filtered) compressed air, in order to generate a laminar air flow which is blown in between the surfaces.

In a further variant, prior to the (areal) placing operation, a subregion of the first surface of the first component, said subregion being formed in particular at a lateral edge of the first surface, is brought into contact with the second surface of the second component. If when the second component is approached the robot hand or the gripping device which holds the first component is not oriented with its longitudinal axis parallel to the normal direction to the second surface, but rather obliquely or at an angle, only a subregion of the first surface strikes against the second surface during the approach. Here, the first surface typically contacts the second surface only at its lateral edge, wherein the force exerted upon first contact between the first surface and the second surface is generally selected to be so low that optical contact bonding does not occur. The force exerted on the second component in the subregion by the robot or by the first component should therefore generally not exceed the weight force and should lie in the order of magnitude of e.g. about 10 N.

The subregion with which the first component contacts the second component should be positioned on the second surface such that the first component no longer needs to be displaced relative to the second component during the subsequent areal placing operation. Ideally, the subregion at the lateral edge of the first surface contacts a subregion at the lateral edge of the second surface.

In a further variant, the contact between the subregion of the first surface and the second surface is detected, specifically preferably on the basis of a torque exerted on the robot by the second component. The robot, more precisely a robot hand or gripping device of the robot, holds the first component during the step of placing onto the second component, wherein a longitudinal axis of the gripping device, for example of the robot hand, about which the latter is rotatable, is typically located approximately in the center of the first surface. If during the movement of the robot or the gripping device the subregion, which is laterally offset with respect to the longitudinal axis or central axis of the robot, of the first surface of the first component comes into contact with the second surface, a torque is exerted on the robot upon contact with the second surface. This torque can be measured with the aid of at least one torque sensor which is mounted on the robot or on at least one joint of the robot. However, the first contact between the subregion of the first surface and the second surface can also be detected in another way, e.g. optically or with a contact sensor based on a different measuring principle.

In a further variant, the first surface of the first component and the second surface of the second component are oriented at a predefined angle with respect to one another during the contacting of the subregion. The predefined angle may be selected to be relatively large, e.g. more than about 10° or 15°. If during the contacting in the subregion the first component is oriented at a large angle relative to the second component, the risk of unintentional optical contact bonding can be minimized. In addition, the first component can be rotated in a controlled manner for the areal placing onto the second component, as described below.

In a further variant, the first component is rotated about the abutting subregion until the first surface of the first component abuts areally against the second surface of the second component. As has been described further above, during the areal placing operation, an air film is formed between the first surface and the second surface if an excessive contact pressure is not exerted on the second component. The rotation of the first component about the subregion makes it possible to effect the placing with a controlled (rotational) movement, ideally without an additional translational movement of the first component being required for this purpose. The robot generally allows small compensating movements of the first component during the rotational movement, in order to reduce or compensate for excessive forces or torques.

In a further variant, the areal abutment of the first surface of the first component against the second surface of the second component is detected, specifically preferably on the basis of a torque exerted on the robot by the second component, in particular on the basis of a minimization of the torque exerted on the robot by the second component. If the first surface of the first component has been oriented as desired relative to the second surface of the second component by the robot, the torque exerted on the robot by the second component is typically minimal. As has been described further above, the detection of the areal abutment is not limited to the detection of a torque, but rather may possibly also be effected in another manner, for example by another type of contact sensor or by an optical sensor.

In a further variant, the method comprises: detecting an interference fringe pattern of the air film, which is formed between the two surfaces areally abutting against one another, wherein the detecting of the interference fringe pattern is preferably effected through the second component. It is possibly also possible for the interference fringe pattern to have already been detected during the placing, if the air film has already partially formed. The interference fringe pattern is generated because the two surfaces are not oriented completely parallel to one another.

The detecting of the interference fringe pattern can be used, for example, to identify the optical contact bonding operation or the end of the optical contact bonding operation: if the two components have been optically contact bonded to one another, the interference fringe pattern disappears, since the air film between the two surfaces has been displaced. In this case, the robot can let go of the first component, since it is connected to the second component. If the pressing operation has been carried out by the robot and an interference fringe pattern is still apparent e.g. in a subregion of the two surfaces after the pressing operation, this means that the optical contact bonding was not successful. In this case, the two surfaces which are partially optically contact bonded to one another can be released from one another again, for example by virtue of the robot moving the first component away from the second component again and for example generating a wedge effect. Further measures may also be taken to release the two components from one another again.

In a further variant, a pressing position, at which the first surface is pressed against the second surface, is defined in dependence on the detected interference fringe pattern, in particular in dependence on a direction of extent of the interference fringe pattern. Generally, during the pressing operation, a contact pressure is not applied to the entire first surface, rather a pressing position is selected at which the air film is intended to first be displaced. In this case, the optical contact bonding process is effected proceeding from the pressing position in the manner of a displacement wave, which propagates along the two surfaces and displaces the air film.

On the basis of the orientation of the interference fringes of the interference fringe pattern, it is possible to identify the direction in which the displacement wave of the air film propagates: the displacement wave generally propagates perpendicularly with respect to the direction of the interference fringes. It is therefore favorable for the pressing position to be selected in dependence on the orientation of the interference fringes of the interference fringe pattern. In principle, it is advantageous for the pressing position to be selected at the lateral edge of the first surface. Here, the pressing position is preferably selected to be that position at the lateral edge of the first surface at which the surface has its maximum extent in a direction perpendicular to the direction of extent of the interference fringes.

In a further variant, at least one, preferably a plurality of parallel-oriented, in particular trench-like depressions is/are formed on the first surface of the first component and/or on the second surface of the second component, wherein an orientation of the first component during the areal abutment is selected in dependence on the orientation of the interference fringe pattern relative to a longitudinal direction of the at least one depression.

If one or more depressions are formed in the first component and/or in the second component, the displacement wave of the air film, said wave being generated during the pressing operation, should preferably not propagate perpendicularly with respect to the longitudinal direction of the depression(s), since the displacement wave, and thus the optical contact bonding, may otherwise be stopped at the depression. The displacement wave should therefore be oriented at an angle which differs from 90° with respect to the depression or depressions. Such an orientation of the interference fringe pattern may possibly be achieved by suitable, slight movements of the first component with the aid of the robot.

A parallel orientation of the interference fringes of the interference fringe pattern with respect to the longitudinal direction of the trench-like depression(s) should therefore be avoided. It is particularly favorable for the direction of extent of the interference fringe pattern to be oriented perpendicularly with respect to the longitudinal direction of the at least one depression, i.e. at an angle of 90°. Angles which deviate by at least 30° from the longitudinal direction of the depression(s) have proven favorable for the direction of extent of the interference fringes.

The trench-like depressions may, for example, run substantially rectilinearly in the second component. The depressions are covered by the first component during the optical contact bonding, as a result of which channels are formed in the component part produced during the optical contact bonding. This component part may, for example, be a substrate for a reflective optical element, e.g. for a mirror. In this case, a reflective coating may be applied to the first component prior to or after the optical contact bonding. The reflective coating may be configured, for example, to reflect radiation in the EUV wavelength range or to reflect radiation in the VUV wavelength range. The second component may also comprise depressions for some other reason. If the component part produced during the optical contact bonding is a mirror, the contact surface formed during the optical contact bonding is typically located in the vicinity of the optical used surface of the mirror, to which used surface the reflective coating is applied. It is therefore particularly important in this case that the fewest possible and in particular no large defects occur along the contact surface.

It is also possible for only the first component to comprise depressions, which are covered by the second surface of the second component during the optical contact bonding, as a result of which channels are formed in the component part produced during the optical contact bonding. It is likewise possible for the first component and the second component to comprise depressions. In this case, the depressions in the first component have to be oriented in a suitable, generally parallel, manner with respect to the depressions in the second component during the optical contact bonding. In this case, it is also possible for the orientation of the interference fringe pattern relative to the depressions in the two components to be changed by a suitable orientation of the first component with the aid of small deflections.

It is not absolutely necessary for the first surface of the first component and the second surface of the second component to be of planar form. Rather, the two surfaces may be of complementary form, such that they fit together during the placing operation. By way of example, the first surface may be convexly curved and be placed onto a correspondingly concavely curved second surface, or vice versa.

The material of the first and/or of the second component may be glass, e.g. quartz glass, in particular titanium-doped quartz glass, such as is offered for example under the trade name ULE®, or some other glass. The material of the first and/or of the second component may alternatively be a glass ceramic or a ceramic, e.g. cordierite. Optical contact bonding is in principle also possible with materials other than those mentioned here.

A further aspect of the invention relates to an apparatus for the in particular fully automated optical contact bonding of components, in particular for carrying out the method for the optical contact bonding of components as described further above, comprising: a robot which is configured or programmed to place a first surface of a first component onto a second surface of a second component so as to form an air film, wherein the robot is preferably configured to press the first surface of the first component against the second surface of the second component, in order to optically contact bond the first component to the second component, and a holding device for holding the second component during the placing and during the pressing of the first component, and a ventilation device for generating a laminar gas flow between the first surface of the first component and the second surface of the second component.

For carrying out the placing step and possibly for carrying out the pressing step, the apparatus may comprise a control device which is configured or programmed to control the robot in order to carry out the above-described method or the variants of the above-described method which are carried out with the aid of the robot. The control device may be a suitable piece of hardware and/or software which is able to be programmed to generate commands for the robot and to transmit them to the robot, if the control device is not integrated into the robot.

The use of a robot affords the possibility of adapting the optical contact bonding process to individual components or component geometries. By way of example, a subregion of the first surface in which first contact with the second surface is established, joining movements such as the rotation or the rolling of the first component, the starting side of the optical contact bonding or the pressing position and the introduced forces may be changed without reconstruction being required. In order to achieve this, the robot should comprise at least one joint, generally two or more joints, in order to also be able to carry out a rotational movement in addition to a translational movement of the first component. The first component can be held by a robot hand or a gripping device of the robot arm, which is connected to the robot arm by way of a joint.

Instead of a robot arm, the robot may also comprise a gripping device with a plurality of clamping elements which are each connected to a, for example, telescopic linear unit, in order to clamp the first component at multiple locations which are typically located along the lateral periphery or edge of the first component. With the aid of the linear units, the robot can execute a translational movement of the first component. If the clamping devices are connected to the linear units by way of joints, a rotational movement of the first component can also be effected in addition to the translational movement if, during the movement of the component, the linear units are moved at different speeds or to different extents. Other configurations of the robot or of the kinematic system are also possible.

In one embodiment, the robot comprises at least one sensor, preferably at least one torque sensor, for detecting the areal abutment of the first surface of the first component against the second surface of the second component, and preferably for detecting first contact between a subregion of the first surface and the second surface. The detection can be effected with the aid of a force-torque or torque sensor, as is described further above in conjunction with the method. However, it is also possible for the areal abutment or the first contact between the first surface and the second surface to be detected with a different type of sensor.

In one embodiment, the holding device is configured to orient the second component at an angle with respect to a horizontal plane, in particular vertically. As has been described further above, a robot, which detects whether the first component has been placed, can be used to carry out the placing step and possibly the pressing step on a non-horizontally oriented second component. In particular if the second surface is oriented substantially vertically, it is possible to prevent particles from settling under the action of gravity on the second surface.

In a further embodiment, the apparatus comprises the ventilation device for generating the laminar gas flow between the first surface of the first component and the second surface of the second component, wherein the gas flow is preferably oriented at an angle with respect to a horizontal plane, in particular vertically, or horizontally or substantially horizontally (at an angle of +/−30° with respect to a horizontal plane). The ventilation device may, for example, be what is known as a fan filter unit (FFU), as is used in clean rooms. Such an FFU is typically installed in the region of a top of the apparatus and comprises a fan and a filter, said fan drawing in the air from above and blowing it through the filter into the space between the two surfaces. In this case, the laminar gas or air flow is typically oriented vertically, can pass through a mesh bottom of the apparatus and be deflected with the aid of a flow guiding device, for example with the aid of a flow guiding plate, in order to generate a circulating air flow. The laminar air flow between the two surfaces also makes it possible to considerably reduce the risk of particles being deposited and thus the occurrence of voids during the optical contact bonding.

In a further embodiment, the apparatus comprises a spatially resolving detector, for example a camera, for detecting an interference fringe pattern of the air film, which is formed between the two surfaces areally abutting against one another, wherein the spatially resolving detector is preferably configured to detect the interference fringe pattern through the second component. A camera may be sufficient for the detecting of the interference fringe pattern, but it is also possible for the interference fringe pattern to be detected mechanically with the aid of a white light interferometer or with the aid of another suitable measuring device.

In this case, the second component is transparent to the wavelength(s) detected by the detector during the detection of the interference fringe pattern. These wavelengths may lie, in particular, in the visible wavelength range. The apparatus may also comprise an evaluation device, in order to evaluate the interference fringe pattern and to determine a direction of extent of the interference fringes of the interference fringe pattern. As has been described further above in conjunction with the method, a pressing position can be defined on the basis of the direction of extent of the interference fringes with the aid of the control device. The control device may also be used to correct the orientation of the first component if the direction of extent of the interference fringes is oriented in an unfavorable manner in relation to a longitudinal direction of trench-like depressions formed in the second or possibly in the first component.

The apparatus may also comprise a loading device for the loading with first and/or second components. For this purpose, the loading device may, for example, comprise a loading table on which first and/or second components can be deposited. For the loading, the first/second components may abut against a transport support which is moved e.g. with the aid of a roller table or another suitable handling device into the access region of the robot, which performs the placing of the first component onto the second component. The robot or another suitable handling device may first pick up a second component, in order to position the latter on the holding device. The holding device may be configured to receive the second component in an automated manner and to hold it e.g. with the aid of a suitable holding or clamping device. After the second component has been positioned on the holding device, the robot can pick up a first component or the first component is mounted on the robot and placed, by way of the first surface, areally onto the second surface of the second component in the manner described further above. It is also possible for the robot or another handling device to grip the component part produced during the optical contact bonding and to deposit it in an automated manner at a desired location, possibly on an unloading device provided for this purpose or at a predefined deposition position.

If the apparatus comprises the loading device described further above for the two components and an unloading device in order to unload the component part produced during the optical contact bonding, the apparatus can be used for the fully automated optical contact bonding of the two components. In the fully automated optical contact bonding, no worker or operator is required, but rather all steps of the optical contact bonding process run in an autonomous and fully automated manner in the apparatus.

The (possibly fully automated) apparatus may comprise a mechanical ultrafine cleaning device, which provides quantifiably cleaner surfaces of the components for the subsequent optical contact bonding process. For this purpose, the ultrafine cleaning device may, for example, comprise a nozzle in order to subject the surfaces of the components to a blowing-off operation. It is favorable for the process times of the processes following the ultrafine cleaning, in particular the optical contact bonding process, to be planned in an automated manner and in as efficient as possible a manner in terms of time, such that contamination of the surfaces can be effectively inhibited until the optical contact bonding process has concluded.

The apparatus may additionally comprise an inspection device for pre-process control, in which the surfaces of the components are analyzed in order to check the result of the ultrafine cleaning and possibly repeat it if the result is not satisfactory. As an alternative or in addition, the apparatus may also comprise a (further) inspection device for post-process control, in which the component part formed during the optical contact bonding of the two components is checked for flaws or defects, in particular in the form of air bubbles (voids), which weaken the connection between the two components. The (further) inspection device may quantify and qualify the defects e.g. with regard to number, position, size and possibly defect type and save the corresponding information in a database. The (further) inspection device may comprise a microscope for the detection of the defects, in order to carry out a microscopic inspection of the defects in the plane or in the region of the contact surface in which the optical contact bonding has been effected.

It is possible, but not absolutely necessary, for the apparatus to comprise a central handling or transport device which transports the components and/or the component part, formed during the optical contact bonding, within the apparatus and picks up or deposits them/it at different locations or stations of the apparatus. The handling device may, for example, comprise a robot arm, which may perform the above-described placing and possibly pressing of the surface of the first component. However, it is also possible for the apparatus to comprise two (or possibly more) robots, one robot being used to place and possibly press the first component and the further robot forming the handling device or part of the handling device.

Further features and advantages of the invention will become apparent from the following description of exemplary embodiments of the invention, with reference to the figures of the drawing, which show details essential to the invention, and from the claims. The individual features can be implemented individually in their own right or collectively in any combination in a variant of the invention.

### BRIEF DESCRIPTION OF THE DRAWINGS

Exemplary embodiments are illustrated in the schematic drawing and are explained in the following description. In the figures:

FIG. 1 shows a schematic illustration of an apparatus for the optical contact bonding of two components,

FIGS. 2A and 2B show schematic illustrations of the establishing of first contact between the two components (FIG. 2A) or of the areal abutment (FIG. 2B) of the two components against one another,

FIG. 3 shows a schematic illustration of an interference fringe pattern which is generated in an air film between the two components areally abutting against one another,

FIG. 4 shows a schematic illustration of a robot, which comprises a kinematic system having three linear units, during the approach of the first component toward the second component,

FIG. 5 shows a schematic illustration of an apparatus for the fully automated optical contact bonding of two components,

FIGS. 6A-6C show three respective schematic illustrations of a fully automated measuring and positioning of the two components relative to one another, and

FIGS. 7A-7D show, respectively, schematic illustrations of four different variants of the optical contact bonding process with a robot which comprises a kinematic system.

### DETAILED DESCRIPTION

In the following description of the drawings, identical reference signs are used for identical or functionally identical components.

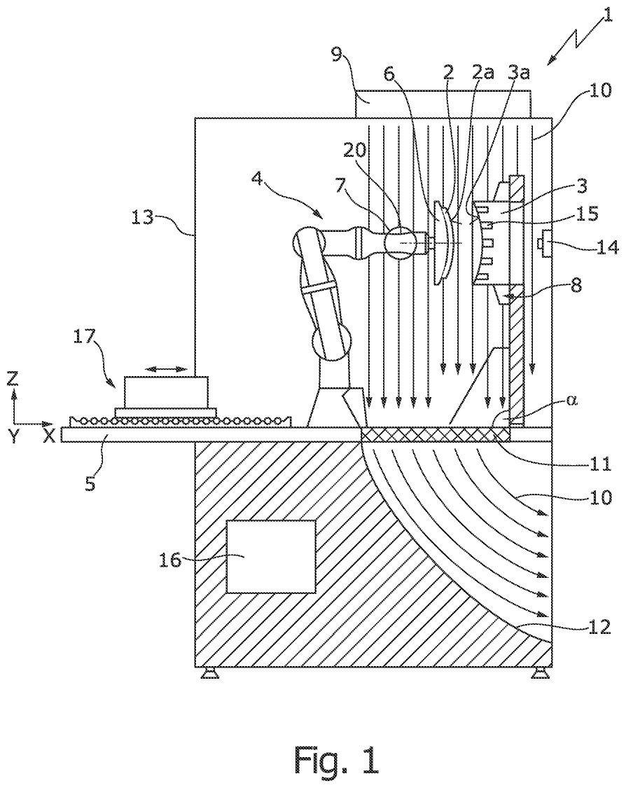

FIG. 1 schematically shows the construction of an apparatus 1 which is configured for the optical contact bonding of two component 2, 3. The apparatus 1 comprises a robot 4 which is configured in the form of a robot arm. In the example shown, the robot 4 is a lightweight robot comprising seven joints. The robot 4 is mounted with a base on a loading table 5. The robot illustrated in FIG. 1 is a lightweight robot from KUKA, however other robots 4 can also be used for the purpose described here, provided they have sufficiently sensitive motor skills.

The robot 4 comprises a gripping device in the form of a robot hand 6, which is connected to the rest of the robot 4 by way of a joint 7. Fastened to the robot hand 6 is the first component 2 which is intended to be optically contact bonded to the second component 3. The fastening or the holding of the first component can be effected with the aid of the robot hand 6.

The second component 3 is mounted on a holding device 8 vertically, i.e. at an angle α of 90°, relative to a horizontal plane X, Y, which corresponds to the support plane of the loading table 5. As a result of the vertical orientation of the second component 3, the accumulation of particles on a second surface 3a of the second component 3, said second surface being intended to be optically contact bonded to a first surface 2a of the first component 2, is reduced, since the particles are no longer able to abut against the vertically oriented second surface 3a.

In the case of the apparatus 1 shown in FIG. 1, the adhesion of particles to the second surface 3a and to the first surface 2a is also reduced by a ventilation device 9 which is mounted in the region of the top of the apparatus 1. In the example shown, the ventilation device 9 is configured as what is known as a fan filter unit (FFU), as is used in clean rooms. The ventilation device 9 comprises a fan and a filter, said fan drawing in air from above and blowing it in the form of a laminar air flow 10 through the filter into the space between the two surfaces 2a, 3a. In the example shown, the laminar air flow 10 is oriented vertically, i.e. in a Z direction. The air flow 10 passes through a mesh bottom 11 of the loading table 5 and is deflected at an air guiding plate 12, before the air is conducted out of a housing 13 of the apparatus 1, in order to form a circulating air flow. The laminar air flow 10 between the two surfaces 2a, 3a also makes it possible to considerably reduce the risk of particles being deposited and thus the occurrence of voids during the optical contact bonding of the two components 2, 3. The clean room class of the apparatus 1 may in particular possibly be increased as a result of the ventilation device 9.

The apparatus 1 also comprises a spatially resolving detector 14 in the form of a camera, which is mounted on a side of the second component 3 that faces away from the second surface 3a. The detector 14 allows the second surface 3a and also the first surface 2a to be observed through the second component 3. In the example shown, the second component 3, like the first component 2, is formed from titanium-doped quartz glass, more precisely from ULE®, which is transparent to visible wavelengths, thus making the observation through the second component 3 possible. However, the first component 2 and the second component 3 may also be formed from other materials.

In the example shown in FIG. 1, the first component 2 is of substantially disk-like form and forms a cover for covering the trench-like depressions 15 formed on the second surface 3a of the second component 3. If the first component 2 is connected at the first surface 2a to the second surface 3a of the second component 3, the cross section of the depressions 15 is closed, and channels which are suitable for being flowed through by a cooling medium are formed in the optical component part produced here. In the example shown, the optical component part is a substrate for a mirror for EUV lithography. In a coating process following the connection of the two components 2, 3, a reflective coating which reflects EUV radiation is applied to a surface of the first component 2 that faces away from the first surface 2a.

As can be seen in FIG. 1, the two surfaces 2a, 3a are congruent with respect to one another, i.e. the first surface 2a is convexly curved and the second surface 3a is concavely curved, wherein the two radii of curvature correspond. The congruence of the two surfaces 2a, 3a is a prerequisite for the optical contact bonding of the two components 2, 3. The two surfaces 2a, 3a must also be sufficiently smooth and free from impurities. The two surfaces 2a, 3a are therefore cleaned prior to the optical contact bonding.

In the example shown, the robot 4 is controlled during the optical contact bonding operation described below by a control device 16 which also controls the loading of the apparatus 1 with first and/or second components 2, 3 with a loading device 17. The control device 16 is also connected to the detector 14 in terms of signaling and comprises an evaluation device in order to evaluate the image captured by the detector 14.

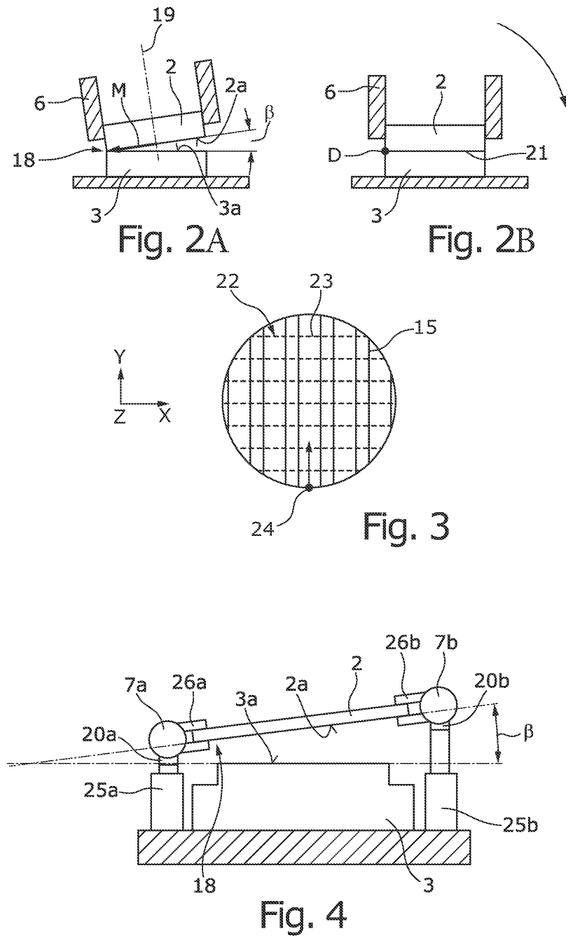

The method sequence during the optical contact bonding is explained below with reference to FIGS. 2A and 2B, in which the two surfaces 2a, 3a are illustrated in planar form for the sake of simplicity.

First of all, the robot 4 is used to move the first component 2 closer to the second component 3 until a subregion 18 of the first surface 2a of the first component 2 bears against the second surface 3a. The subregion 18 of the first surface 2a is formed at the lateral edge of the first surface 2, as can be seen in FIG. 2A. Here, the subregion 18 at the edge of the first surface 3a bears against a lateral edge of the second surface 3a. As can also be seen in FIG. 2A, the first surface 2a is oriented at an angle R with respect to the second surface 3a, which is about 15° but can also be selected to be larger or smaller. The angle R is predefined by the control device 16 and is selected to be relatively large, in order to prevent unintentional optical contact bonding of the two surfaces 2a, 3a. The force exerted on the second component 3 by the robot 4 during the first contact should also not be too great: the force should generally not be greater than if the first component 2 were pressed with its weight force against the second component 3. The force exerted on the second component 3 should generally lie in the order of magnitude of about 10 N.

The first contact between the first surface 2a and the second surface 3a in the subregion 18 can be detected on the basis of a torque M, which is exerted on the first component 2 by the second component 3 and on the robot 4, more precisely on the longitudinal axis 19 of the robot hand 6 or on the joint 7, by said first component. As can be seen in FIG. 2A, the longitudinal axis 19 runs substantially centrally through the first surface 2a of the first component 2. The subregion 18, in which the first contact is effected, of the first surface 3a is spaced apart from the longitudinal axis 19 of the robot hand 6, the spacing being indicated by an arrow in FIG. 2A. Therefore, upon first contact of the subregion 18, a torque M is exerted on the robot 4. This torque M is detected by the robot 4 at the joint 7 with the aid of a joint moment sensor 20, which is illustrated in FIG. 1.

On the basis of the detected torque M, which is a vector quantity, the control device 19 can identify which direction or along which axis of rotation D the first component 2 has to be rotated in order to close the angle R and to place the first component 2 areally on the second component 3. Here, it is not absolutely necessary to know the direction of the torque M. The axis of rotation D during the rotation of the first component 2 is located in the subregion 18 in which the first contact takes place, i.e. the first component 2 is rotated about the already abutting subregion 18 or the corresponding contour at the edge of the first surface 2a.

FIG. 2B shows the two components 2, 3 in a position abutting against one another after the rotational movement has concluded. Owing to the relatively small forces exerted on the second component 3 during the rotational movement, the optical contact bonding is not triggered during the rotational movement. The first surface 2a of the first component 2 therefore abuts areally against the second surface 3a of the second component 3 so as to form an air film 21. The air film 21 has a thickness which generally lies in the order of magnitude of micrometers.

The areal abutment of the first surface 2a of the first component 2 against the second surface 3a of the second component 3 is also detected with the aid of the torque sensor 20 of the robot 4: The torque M exerted on the first component 2 by the second component 3 in the areally abutting position shown in FIG. 2B is virtually zero or undershoots a threshold value, which is detected by the control device 16 as the achievement of the areal abutment. For this purpose, the control device 16 carries out a control action in order to minimize the torque M.

In the example shown, with the components 2, 3 areally abutting against one another, the optical contact bonding is triggered by virtue of the first surface 2a of the first component 2 being pressed against the second surface 3a of the second component 3 at a pressing position 24 which is formed at the circular, peripheral edge of the first surface 2a. The pressing position 24 is illustrated in FIG. 3, which shows the image, captured by the spatially resolving detector 14, of the air film 21 between the first surface 2a of the first component 2 and the second surface 3a of the second component 3. As can be seen in FIG. 3, the pressing position 24 is a position which is formed at the lateral edge of the, in the projection into the XY plane, circular first surface 2a of the first component 2.

Also visible in FIG. 3 are the trench-like depressions 15 in the second surface 3a of the second component 3, the longitudinal direction of said depressions corresponding to the Y direction of the XYZ coordinate system shown in FIG. 1. Also visible in FIG. 3 is an interference fringe pattern 22, which is produced in the air film 21 owing to the not fully parallel orientation of the two surfaces 2a, 3a areally abutting against one another. In the example shown in FIG. 3, the interference fringes 23 of the interference fringe pattern 22 are illustrated in dashed form in order to better distinguish them from the trench-like depressions 15. The respective interference fringes 23 have a direction of extent which corresponds to the X direction of the XYZ coordinate system.

The direction of extent X of the interference fringes 23 is thus oriented perpendicularly with respect to the longitudinal direction Y of the trench-like depressions 15. This is favorable since a displacement wave, which displaces the air film 21 out of the intermediate space or out of the gap between the two surfaces 2a, 3a, propagates transversely with respect to the interference fringes 23, i.e. in the Y direction, as indicated by an arrow in FIG. 3. Here, the displacement wave proceeds from the pressing position 24 at which the first surface 2a of the first component 2 is pressed against the second surface 3a of the second component 3. As soon as the displacement wave has completely displaced the air film 21 between the two components 2, 3, the two components 2, 3 are optically contact bonded to one another and held by molecular forces of attraction.

Both the pressing position 24 and the orientation of the first component 2 or of the first surface 2a relative to the second component 3 or to the second surface 3a are defined in dependence on the orientation of the interference fringe pattern 22, more precisely on the direction of extent X of the interference fringes 23 of the interference fringe pattern 22. Here, the orientation of the first component 2, more precisely of the first surface 2a, can be changed by small movements of the first component 2 with the aid of the robot 4 in such a way that the direction of extent X of the interference fringes 23 is oriented substantially perpendicularly with respect to the longitudinal direction Y of the trench-like depressions 15. This makes it possible for the displacement wave, which displaces the air film 21, to not impinge on the longitudinal side of one of the trench-like depressions 15, since in this case the displacement wave might be stopped at the trench-like depression 15. Such an orientation of the first component 2 is also possible if the trench-like depressions 15 are formed in the first component 2 instead of in the second component 3, or if both the first component 2 and the second component 3 comprise trench-like depressions 15.

Since the displacement wave propagates perpendicularly with respect to the interference fringes 23 of the interference fringe pattern 22, the pressing position 24 is selected at that position at the peripheral edge of the first surface 2a at which the surface 2a has its maximum extent perpendicularly with respect to the direction of extent X of the interference fringes 23. In the example shown in FIG. 3, the pressing position 24 is selected at the bottommost location of the edge of the surface 2a in the Y direction. The pressing position 24 may also be selected at the uppermost location of the edge of the surface 2a in the Y direction. In principle, other pressing positions 24 may also be defined by the control device 16, wherein the definition of a pressing position 24 at the edge of the first surface 2a has proven to be favorable.

The successful optical contact bonding of the two components 2, 3 can also be checked with the aid of the spatially resolving detector 14: if the optical contact bonding was successful, the interference fringe pattern 22 in the captured image should completely disappear. If this is not the case, the two components 2, 3 may possibly be released from one another again, if the robot 4 exerts a sufficiently great force on the components 2, 3. It is also possible for the step of placing the two components 2, 3 onto one another to be interrupted or restarted, e.g. if the torque M cannot be minimized as desired. In this case, it is for example possible for a different subregion 19, which establishes the first contact with the second surface 3a, of the first surface 2a to be selected, as a result of which the axis of rotation D about which the first component 2 is rotated changes.

The component part which is formed during the optical contact bonding of the two components 2, 3 and which, in the example shown, is a mirror or a substrate for a mirror can be unloaded with the aid of the robot 4. Here, the robot 4, more precisely the robot hand 6, can grip or hold the two components 2, 3. However, it is also possible for the robot 4 to grip the assembled component part only on the first component 2, if the connection formed during the optical contact bonding is stable enough.

FIG. 4 shows the approach of the first component 2 toward the second component 3, the surface 2a of said first component being oriented, as in FIG. 2A, at a predefined angle R with respect to the surface 3a of the second component 3, in an alternative configuration of the robot 4. The robot 4 shown in FIG. 4 comprises a kinematic system having three or more linear units, of which only two linear units 25a,b are illustrated in the sectional illustration of FIG. 4. The linear units 25a, 25b, . . . each comprise a motor and are of telescopic form. A clamping device 26a, 26b, . . . in the form of a clamping gripper is connected at a free end of a respective linear unit 25a, 25b, . . . by way of a respective joint 7a, 7b, Of the clamping devices 26a, 26b, . . . , only two clamping devices 26a,b are illustrated in FIG. 4. Correspondingly, only two joints 7a, 7b are illustrated in FIG. 4 as well. The clamping devices 26a, 26b, . . . form a gripping device 6 of the robot 4 and engage at different positions along the lateral edge of the first component 2.

With the aid of the joints 7a, 7b, . . . , it is possible to also implement a controlled rotational or tilting movement of the first component 2 in addition to a translational movement of the first component 2 by virtue of the linear units 25a, 25b, . . . being deflected to different extents. The linear units 25a, 25b, . . . or the clamping devices 26a, 26b, . . . mounted thereon may possibly be precisely positioned with the aid of piezo actuators.

In order to measure the torque M exerted on the first component 2 by the second component 3, a respective torque sensor 20a, 20b, . . . (force-torque sensor) is mounted on a respective joint 7a, 7b, . . . of the robot 4, of which only two torque sensors 20a,b are illustrated in FIG. 4. On the basis of the forces which are measured by the torque sensors 20a, 20b, . . . and which are exerted on the respective joints 7a, 7b, . . . , it is possible, in an analogous manner to the robot 4 described further above, for a force-torque control of the optical contact bonding method to be effected, which is based solely on the feedback from the torque sensors 20a, 20b, . . . . In this way, it is in particular possible for the first contact between the subregion 18 of the first surface 2a and the second surface 3a of the second component 3 and the areal abutment of the first surface 2a of the first component 2 against the second surface 3a of the second component 3 to be detected. For the control of the method, it is generally sufficient for force sensors, instead of force-torque sensors 20b, . . . , to be mounted on the joints 7a, 7b, . . . of the respective linear units 25a, 25b, since the torque M exerted on the first component 2 can also be determined from the forces acting at different locations. As illustrated in FIG. 1, the holding device 8 for the second component 3 may be oriented vertically, however it is also possible for the second component 3 to be oriented horizontally, as is described further below.

The optical contact bonding of the two components 2, 3 which is described further above can be followed, for example, by a tempering step, in which a permanent connection between the two components 2, 3 is established; however, this is not absolutely necessary.

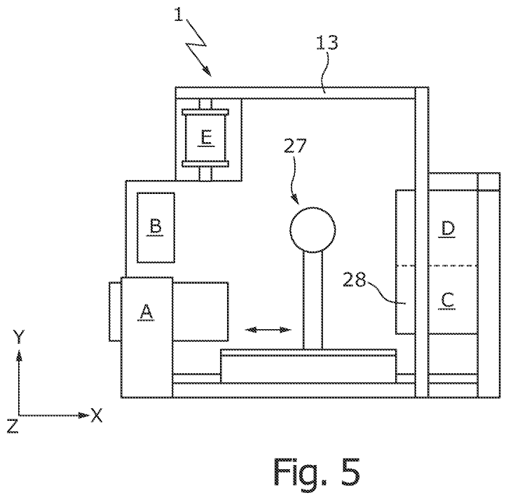

FIG. 5 shows, in highly schematic form, a top view of an apparatus 1 which, like the apparatus 1 shown in FIG. 1, is configured for the fully automated optical contact bonding of two components 2, 3, which are not illustrated graphically in FIG. 5. The apparatus 1 comprises a central handling device 27 which is used to pick up and deposit the two components and the component part formed during the optical contact bonding. The handling device 27 is also used to transport the components or the component part between five machine stations A to E, which are located in an interior space of a housing 13 of the apparatus 1, said interior space being a clean room as in FIG. 1. The handling device 27 comprises a robot arm which is displaceably mounted on a side wall of the housing 13 of the apparatus, as indicated by a double-headed arrow in FIG. 5. The handling device 27 may also be configured differently.

During the fully automated optical contact bonding, the machine stations A to E are passed through successively. The first machine station A is an input station, at which the two components are introduced via an air lock into the interior space of the housing 13. It is for example possible to use a conveyor belt to transport the components into the interior space. The input station A of the apparatus 1 comprises an ultrafine cleaning installation, at which the surfaces of the components are clean. The ultrafine cleaning installation is configured to blow off particles deposited on the surfaces with the aid of compressed air. However, the ultrafine cleaning installation may also clean the surfaces in a different manner. The ultrafine cleaning of a respective component at the input station A can be effected without said component needing to be held by the handling device 27.

After the ultrafine cleaning has concluded, the respective component is transported with the aid of the handling device 27 to the second machine station B, at which an inspection device for automated pre-inspection of the respective component, more precisely of that surface of the component which is connected to the surface of the other component during the optical contact bonding process, is arranged. The inspection device may, for example, comprise a camera or the like, in order to inspect the respective surface. If it is determined during the inspection that the cleanliness of the surface is not sufficient for the subsequent optical contact bonding process, the component can be transported back to the ultrafine cleaning device at the input station A by the handling device 27 and the ultrafine cleaning can be repeated.

If the surface of the respective component has a sufficient surface quality, said component is transported by the handling device 27 to the third machine station C, at which an optical contact bonding module 28 for the optical contact bonding of the two components to one another is arranged, said module being described in more detail further below. During the optical contact bonding, a component part is formed from the two components, said component part being transported with the handling device 27 to a fourth machine station D, at which a further inspection device for post-inspection of the component part is arranged. For this purpose, the further inspection device may, for example, comprise a microscope which checks whether defects, e.g. inclusions in the form of air bubbles, were formed along a for example planar contact surface at which the two components 2, 3 were connected to one another during the optical contact bonding. The defects are quantified and qualified by the further inspection device with regard to number, position, size and possibly defect type. The information obtained during the inspection is stored by the further inspection device in a database which can be accessed by a machine operator located outside of the housing 13.

The component part assembled during the optical contact bonding is transported by the handling device 27 from the fourth machine station D to a fifth machine station E, which is an output station at which the component part is deposited and transported via an air lock out of the interior space of the housing 13.

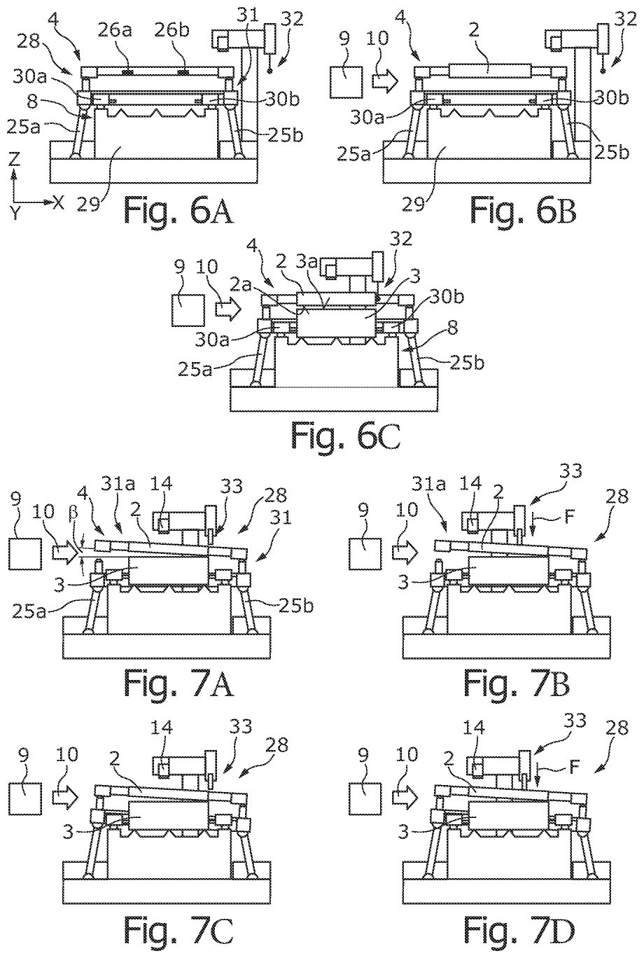

FIGS. 6A-6C and FIGS. 7A-7D show a detail illustration of the optical contact bonding module 28 of FIG. 5. The optical contact bonding module 28 comprises a holding device 8 for holding the second component 3. In the example shown, the holding device 8 is configured to hold the second component 3 in a horizontal orientation and comprises a support block 29 for this purpose, the second component 3 being placed on a plurality of support points on the upper side of said support block. As can be seen in FIG. 6C, that surface 3a of the second component 3 to which the surface 2a of the second component 2 is optically contact bonded also runs horizontally in the example shown, i.e. in a plane XY perpendicular to the direction of gravity Z. The holding device 8 comprises a plurality of clamping devices 30a, 30b, . . . , of which only two are illustrated in FIGS. 6A-6C, which engage laterally on the second component 3 in order to secure it in a desired position in the XY plane.

The optical contact bonding module 28 also comprises a robot 4 which, like the robot 4 shown in FIG. 4, comprises a kinematic system having three or more linear units, of which only two linear units 25a,b are illustrated in FIGS. 6A-C. The linear units 25a, 25b, . . . each comprise a motor and are of telescopic form. The linear units 25a, 25b, . . . are connected, on their upper side, in an articulated manner to a supporting frame 31, on which clamping devices 26a, 26b, indicated schematically in FIG. 6A are mounted, said clamping devices engaging laterally on the first component 2 in order to hold it for the optical contact bonding process, as illustrated in FIG. 6B and in FIG. 6C.

As can be seen in FIGS. 6A-6C, the optical contact bonding module 28 also comprises a measuring head 32. The measuring head 32 is mounted on an XYZ coordinate guide which allows the measuring head 32 to be displaced in three spatial directions, i.e. allows it to be moved freely in space. The measuring head 32 senses the position of the two components 2, 3 in space, as indicated in FIG. 6C for the first component 2. The measuring head 32 makes it possible to acquire the position of the two components 2, 3 in space and to thus also acquire the relative position thereof with respect to one another. The orientation or the position of the two components 2, 3 can be set, and if necessary corrected, with the aid of the clamping devices 26a, 26b, . . . of the robot 4 or with the aid of the clamping devices 30a, 30b of the holding device 8.

As can also be seen in FIGS. 6B and 6C, a ventilation device 9 is used to generate a laminar gas flow 10, indicated by an arrow, between the first surface 2a of the first component 2 and the second surface 3a of the second component 3. As can be seen in FIGS. 6B and 6C, the laminar gas flow 10 runs substantially in the horizontal direction. The ventilation device 9 may be configured to branch off the horizontally oriented laminar gas flow 10 from a gas flow provided by a fan filter unit (FFU), as has been described in conjunction with FIG. 1; however, this is not absolutely necessary. It is favorable for the laminar gas flow 10 to only be generated if at least one of the two components 2, 3 is received in the optical contact bonding module 28. The laminar gas flow 10 is also maintained during the optical contact bonding of the two components 2, 3, which is described in more detail below in conjunction with FIGS. 7A-7D. The laminar gas flow 10 does not necessarily have to be oriented horizontally, provided that it is ensured that said gas flow runs between the surface 2a of the first component 2 and the surface 3a of the second component 3 during the optical contact bonding.

As has been described further above in conjunction with FIGS. 2A and 2B and FIG. 4, the two components 2, 3 are oriented at an angle R during the optical contact bonding (cf. FIG. 7A) and brought into contact with one another. For the pressing of the first component 2 against the second component 3, the robot 4 comprises a force module 33 which is mounted on the XYZ linear guide described further above. The force module 33 comprises an extendable, bar-like pressing element, in order to exert an initial force for the optical contact bonding on the two components 2, 3 which are oriented relative to one another. In the example shown, the bar-like pressing element is pressed against the upper side of the first component 2, but the force required for the optical contact bonding may also be applied in a different manner. By way of example, the initial force may be applied with the aid of the telescopic linear units 25a, 25b . . . of the kinematic module of the robot 4, which also brings about the tilting of the first component 2 held in the supporting frame 31.

As has been described further above in conjunction with FIGS. 2A and AB and FIG. 4, the first component 2 is connected to the second component 3 upon the further lowering of the first component 2 in an initial tilting direction so as to form a contact surface. During this optical contact bonding process, instabilities occur which have to be controlled in order to ensure complete optical contact bonding of the two components 2, 3. In order to monitor the optical contact bonding process, an in-line monitoring system is used, in which the interference fringe pattern 22 described further above is detected with the camera 14 which is mounted in this case on the XYZ coordinate guide. The in-line monitoring system also contains the information regarding the respective orientation of the two components 2, 3 relative to one another (based on the optical contact bonding surface or contact surface). The interference fringe patterns 22 are interpreted with the aid of a suitable piece of software and/or hardware of the apparatus 1 and data, with the aid of which the optical contact bonding process can be kept stable, are made available to the robot 4 or to the force module 33.

There are various possibilities for the implementation of the optical contact bonding process, of which four possibilities are indicated in highly schematic form in FIGS. 7A-7D. In FIG. 7A and FIG. 7B, the optical contact bonding is effected in an only partially guided manner, i.e. the position of the first component 2 is not completely defined during the lowering operation. In the examples shown in FIGS. 7A and 7B, this is achieved by virtue of the fact that an upper part 31a of the supporting frame 31 is tilted relative to the rest of the supporting frame 31 or to the lower part thereof. In this case, the lower part of the supporting frame 31 remains in a horizontal orientation during the optical contact bonding, since the length of the telescopic linear units 25a, 25b, . . . is kept constant. The upper part 31a of the supporting frame 31 has a free end or a free side, the position of which is not precisely predefined by the robot 4 or by the kinematic module. By contrast, in the examples shown in FIGS. 7C,D, the movement of the first component 2 is effected in a completely guided manner, specifically by virtue of the entire supporting frame 31 being tilted with the aid of the telescopic linear units 25a, 25b, . . . , as described further above in conjunction with FIG. 4.

FIG. 7A and FIG. 7C show an optical contact bonding process in which the force module 33 no longer applies any force to the first component 2 during the lowering operation, i.e. after the initial force has been applied, i.e. the optical contact bonding process is not a force-controlled optical contact bonding process. By contrast, in the optical contact bonding processes shown in FIG. 7B and FIG. 7D, a force F is also applied to the upper side of the first component 2 with the aid of the pressing element of the force module 33 during the optical contact bonding process, as indicated by an arrow. The optical contact bonding processes shown in FIGS. 7B and 7D are therefore force-controlled processes.

In the optical contact bonding process shown in FIG. 7B and FIG. 7D, the measured data provided by the in-line monitoring system described further above are used by the force module 33 in order to define the pressing position at which, the movement direction in which, and the magnitude with which the force module 33 has to apply a force to the first component 2 in order to keep the optical contact bonding process stable.

As has been described further above, the conclusion of the optical contact bonding process, in which the two components 2, 3 are completely connected to one another at a contact surface, can be detected on the basis of the disappearance of the interference fringe pattern 22, since in this case the air film between the two surfaces 2a, 3a has been completely displaced. If the interference fringe pattern 22 does not disappear, the optical contact bonding process can be terminated or the two components 2, 3 can be separated from one another again by the application of a counterforce.

What is claimed is:

1. A method for optical contact bonding of components, comprising:
placing a first surface of a first component onto a second surface of a second component, thereby forming an air film, wherein said placing of the first component is carried out by robot,
pressing the first surface of the first component against the second surface of the second component, thereby forming the optical contact bonding of the first component to the second component and
generating a laminar gas flow between the first surface of the first component and the second surface of the second component with a ventilation device.

2. The method as claimed in claim 1,
wherein said pressing of the first component is carried out by robot.

3. The method as claimed in claim 1, further comprising orienting the second component at an angle (α) with respect to a horizontal plane during said placing of the first component.

4. The method as claimed in claim 3, wherein the second component is oriented vertically with respect to the horizontal plane during said placing of the first component.

5. The method as claimed in claim 1, wherein the laminar gas flow is oriented at an angle (α) with respect to a horizontal plane.

6. The method as claimed in claim 1, further comprising, prior to said placing, bringing a subregion of the first surface of the first component into contact with the second surface of the second component.

7. The method as claimed in claim 6, wherein the subregion brought in contact with the second surface of the second component comprises a lateral edge of the first surface.

8. The method as claimed in claim 6, further comprising: detecting the contact between the subregion of the first surface and the second surface.

9. The method as claimed in claim 8, wherein said detecting of the contact between the subregion of the first surface and the second surface comprises exerting a torque on the robot by the second component.

10. The method as claimed in claim 6, wherein the first surface of the first component and the second surface of the second component are oriented at a predefined angle (β) with respect to one another during the contacting of the subregion.

11. The method as claimed in claim 6, wherein the first component is rotated about the subregion until the first surface of the first component abuts areally against the second surface of the second component.

12. The method as claimed in claim 1, further comprising: detecting an areal abutment of the first surface of the first component against the second surface of the second component.

13. The method as claimed in claim 12, wherein said detecting of an areal abutment comprises minimizing the torque exerted on the robot by the second component.

14. The method as claimed in claim 1, further comprising: detecting an interference fringe pattern of an air film formed between the first and the second surfaces areally abutting against one another.

15. The method as claimed in claim 14, wherein a pressing position, at which the first surface is pressed against the second surface, is defined in dependence on the detected interference fringe pattern.

16. The method as claimed in claim 14, wherein at least one parallel-oriented trench-like is formed on the first surface of the first component and/or on the second surface of the second component, and wherein an orientation of the first component during the areal abutment is selected in dependence on the orientation of the interference fringe pattern relative to a longitudinal direction (Y) of the at least one trench-like depression.

17. An apparatus for automated optical contact bonding of components, comprising:
a robot configured to place a first surface of a first component onto a second surface of a second component, to form an air film,
a holding device configured to hold the second component during said placing, and
a ventilation device configured to generate a laminar gas flow between the first surface of the first component and the second surface of the second component.

18. The apparatus as claimed in claim 17, wherein
the robot is further configured to press the first surface of the first component against the second surface of the second component, to thereby optically contact bond the first component to the second component.

19. The apparatus as claimed in claim 17, wherein the robot comprises at least one sensor, configured to detect the areal abutment of the first surface of the first component against the second surface of the second component.

20. The apparatus as claimed in claim 17, wherein the holding device is configured to orient the second component at an angle (α) with respect to a horizontal plane.

21. The apparatus as claimed in claim 17, wherein the ventilation device is configured to orient the laminar gas flow at an angle (α) with respect to a horizontal plane.

22. The apparatus as claimed in claim 17, further comprising:
a spatially resolving detector configured to detect an interference fringe pattern of an air film formed between the first and the second surfaces areally abutting against one another.
